(19) United States
(12) Patent Application Publication
(10) Pub. No.: US 2026/0236731 A1
(43) Pub. Date: Aug. 13, 2026

(54) HARDWARE DESIGN SYSTEM FOR ON-DEVICE ARTIFICIAL INTELLIGENCE OF LARGE LANGUAGE MODELS

(71) Applicant: Kwangwoon University Industry-Academic Collaboration Foundation, Seoul (KR)

(72) Inventors: Young Ho SEO, Seoul (KR); Jung-Woo KIM, Seoul (KR)

(21) Appl. No.: 19/063,373

(22) Filed: Feb. 26, 2025

(30) Foreign Application Priority Data
Feb. 12, 2025 (KR) 10-2025-0017829

(51) Int. Cl. G06N 3/04

(52) U.S. Cl. CPC G06N 3/04

(57) ABSTRACT

Provided is a hardware design system for on-device artificial intelligence of large language models, which performs full integer arithmetic using a fixed-point simulation on commercially available large language models optimize large-scale language models for hardware development for on-device use, and includes: a LLM model input unit for receiving an LLM model; a simulation data input unit for receiving simulation data; a RON extraction unit for extracting a RON configuration from a configuration of the LLM model; a fixed-point simulator for simulating an execution of the LLM model by using the simulation data; and a bit configuration setting unit for setting a bit configuration of each RON node in the RON configuration. Thus, all computation are converted to fixed-point integer format, so that floating point dependency is removed, and accordingly, the possibility of bottlenecks in the floating-point computations due to the need for floating-point restoration is eliminated.

### BACKGROUND OF THE INVENTION

### 1. Field of the Invention

The present invention relates to a hardware design system for on-device artificial intelligence of large language models, which performs full integer arithmetic using a fixed-point simulation on commercially available large language models such as LLaMA3-8B (LLAMA3-8B-chat) to optimize large-scale language models for hardware (H/W) development for on-device use.

In addition, the present invention relates to a hardware design system for on-device artificial intelligence of large language models, which converts all arithmetic including the Softmax function and normalization arithmetic to fixed-point integer format, thereby implementing full integer arithmetic that do not require floating-point hardware.

### 2. Description of the Related Art

Large-scale language models (LLMs) exhibit outstanding performance at various natural language processing tasks and have been increasingly used in on-device environments.

The large language model serves as a successful model in the field of natural language processing. LLM has developed rapidly with the advent of the Transformer structure and shows excellent natural language processing capabilities based on tokenizer-processing of text. This has evolved into a useful model for generating not only human languages, but also programming languages having complex syntax. The Transformer structure may use an attention mechanism to find correlations between words and sentences and efficiently infer reasonable words to be generated next. There are already several successful LLM models such as ChatGPT, Gemini, Claude, OPT and LLaMA, which are actively utilized in both industry and research.

However, because the capacity of trained parameters becomes larger as performance of LLM increases, models that are difficult to use even in consumer-level GPUs are appearing recently. For example, the LLaMA 3 model has 870 billion parameters. Accordingly, the above LLM model cannot run on a GPU having a limited VRAM or on a mobile device. High-end GPUs such as the RTX4090 or server-grade GPUs such as the A100 and H100 are required to drive these models.

In order to solve problems caused by low computing power, there are studies that reduce off-chip traffic by compressing trained weights with parameters having small bit widths, and reduce computational bottlenecks by implementing integer computations.

The categories for efficiently inferring LLM locally may be mainly divided into two: the Quantization-Aware Training (QAT) scheme and the Post-Training Quantization (PTQ) scheme.

The QAT scheme performs learning by applying quantization at model-specific computation locations in the network. The QAT scheme may achieve good performance because a model is trained to be suitable to the corresponding quantization configuration, however, the QAT for a large-scale LLM may be too expensive for the learning itself.

Thus, there is a Quantized Low-Rank Adaptation (QRoLA) scheme that applies quantization by using an already trained model and additionally performs fine-tuning. This scheme does not directly maintain the mathematical precision of the model and requires a learning process for quantization and fine-tuning. Therefore, it may be effective only in a specific dataset range used for fine-tuning and performance degradation may occur in other scenarios. In addition, in the case where hardware optimization is insufficient, especially when dequantization is required during inference, high-speed inference may also be constrained.

In contrast, the Post-Training Quantization (PTQ) scheme has the advantage of quantizing a pre-trained model without a retraining process. The PTQ scheme is further divided into a weight-only quantization (WOQ) scheme and a weight-activation quantization (WAQ) scheme.

GPTQ is an example of the weight-only quantization (WOQ) scheme. The WOQ scheme may quantize only the weights to 4 bits or 8 bits using Hessian-free quantization optimization but minimize performance degradation. However, since it is the weight-only quantization, there is still a limitation that activation values are required to be calculated with floating points. In addition, since the activation values are processed as floating point numbers, this may cause a bottleneck in high-speed inference.

SmoothQuant, AWQ or the like may be proposed as a scheme for solving the above bottleneck of the weight-only-based PTQ. For example, SmoothQuant has the feature of calibrating large-variance activations in large-scale LLMs by applying 8-bit quantization through scale equalization of weights and activation values, and it simultaneously quantizes the weights and the activation values to 8 bits, but has the disadvantage of having a scaling overhead. Meanwhile, AWQ is a PTQ scheme for calibrating a layer-by-layer activation value range, however, has the limitation that a more detailed calibration step is required.

In addition, SpinQuant proposes a scheme of alleviating outliers and increasing quantization precision by combining PTQ and QAT to apply a rotation matrix to weights and activation values of a model. This rotation matrix is appropriately adjusted using optimization techniques such as Cayley SGD, and allows intermediate weights and activation values to be quantization-friendly without affecting network outputs. The above PTQ/QAT hybrid scheme is a good approach in an aspect of accuracy maintenance. However, there are still constraints in an aspect of a dedicated hardware accelerator design since additional fine-tuning and concurrent software-hardware optimization are required, and this also cannot resolve the dataset dependency in fine-tuning.

There are also studies that design dedicated hardware accelerators for supporting specific quantization configurations by using the PTQ scheme without modifications or with slight modifications. Especially in the case of OliVe, large weight compression of 4 bits is achieved while sacrificing non-outlier values among adjacent weight values. However, quick acceleration can be achieved only when hardware capable of decoding outlier-victim pairs is present. In addition, it is difficult for even these dedicated hardware accelerators to handle the full function of LLM in a pure integer-only manner. In particular, it remains a challenging task to fully implement exponential calculations and normalization processes, in arithmetic such as the Softmax, by using integer arithmetic. In other words, QAT and PTQ focus on the trade-off between model accuracy and bit width, and PTQ-based hardware implementations focus on inference speed.

Overall, existing studies have mainly used schemes that assume identical or consistent quantization configurations or set precision at a specific layer or arithmetic location in a lump. This approach alone may fail to sufficiently analyze which benefits are obtained in the overall model accuracy when higher (or lower) precision is applied to some layers or computational nodes. For example, with respect to the small positive value epsilon (1e⁻⁵) used to prevent division by zero when LLM is trained, existing quantization schemes do not specify what bit configuration the epsilon is required to have in fixed-point computations. Even in successful LLMs such as LLaMA3, epsilon is used as a hyperparameter having outputs that vary depending on whether epsilon is 1e⁻⁵ or 1e⁻⁶, and even these small constants have sensitive bit configurations.

### SUMMARY OF THE INVENTION

In order to solve the above-described conventional problems, an object of the present invention is to provide a hardware design system for on-device artificial intelligence of large language models, which performs full integer arithmetic using a fixed-point simulation on commercially available large language models such as LLAMA3-8B (LLaMA3-8B-chat) to optimize large-scale language models for hardware (H/W) development for on-device use.

In addition, an object of the present invention is to provide a hardware design system for on-device artificial intelligence of large language models, which converts all arithmetic including the Softmax function and normalization arithmetic to fixed-point integer format, thereby implementing full integer arithmetic that do not require floating-point hardware.

Particularly, an object of the present invention is to provide a hardware design system for on-device artificial intelligence of large language models to define repeatable and one-to-one nodes (RON), which are distinct computation nodes, and find the optimal bit configuration without loss of accuracy through fixed-point simulation in a RON unit.

In other words, it is applied to commercial LLM models such as LLAMA3-8B-Instruct, which is a target model, to determine the appropriate bit precision for each computation node. Constants and bit width of initial values are optimized to improve the accuracy of integer computations.

Specifically, the present invention provides a method of fixed-point structure conversion for enabling efficient in terms of H/W resources and fast inference in terms of performance when LLM is implemented by H/W.

Meanwhile, the present invention uses the massive multitask language understanding (MMLU) evaluation metric instead of the perplexity (PPL) evaluation metric.

To achieve the above mentioned objects, the present invention relates to a hardware design system for on-device artificial intelligence of large language models, which includes: a LLM model input unit for receiving a trained LLM model; a simulation data input unit for receiving simulation data; a RON extraction unit for extracting a RON configuration from a configuration of the LLM model, in which the RON configuration is composed of a repeatable single node (hereinafter referred to as a RON node) representing constants or computations; a fixed-point simulator for simulating an execution of the LLM model by using the simulation data, in which some or all of constants or computations of the LLM model are simulated by fixed-point bit configurations, and the bit configuration of each constant or computation is given; and a bit configuration setting unit for setting a bit configuration of each RON node in the RON configuration, in which a bit configuration of a corresponding RON node is set to perform a simulation through the fixed-point simulator, and a final bit configuration of the corresponding RON node is set based on a result of the simulation.

As described above, according to the hardware design system for on-device artificial intelligence of large language models, integer computations can be achieved without performance degradation in the MMLU benchmark.

In addition, according to the hardware design system for on-device artificial intelligence of large language models, all computations can be converted to fixed-point integer format to eliminate floating-point dependencies, and accordingly, the possibility of bottlenecks in the floating-point computations due to the need for floating-point restoration can be eliminated.

In other words, the existing quantization schemes focus on weight matrix multiplication computations to perform integer conversion, but may cause a bottleneck in floating-point computations because a floating-point restoration is required afterwards. The present invention enables the implementation of full integer computations without floating-point hardware, so that the bottleneck problem can be solved.

In addition, according to the hardware design system for on-device artificial intelligence of large language models, constants and bit width of initial values are optimized and the massive multitask language understanding (MMLU) evaluation metric is used instead of the perplexity (PPL) evaluation metric, thereby verifying performance on various knowledge domains, so that the robustness of the model can be ensured and high efficiency can be maintained even in various on-device environments.

In other words, the present invention can utilize optimal fixed-point bits so as to implement a model capable of integer computations without performance degradation. According to the present invention, integer computations can be achieved without performance degradation in the MMLU benchmark.

In addition, the present invention does not degrade original LLM performance (FP16) and the bit precision required for each node is determined in advance, so that fast and efficient accelerators utilizing fixed-point operators can be designed.

In addition, according to the present invention, the quantization and fixed-point simulation schemes enable the extraction of node-specific test vectors required in the hardware co-design process so as to be suitable for an appropriate fixed-point configuration, so that advantages in terms of hardware verification can be provided.

### BRIEF DESCRIPTION OF THE DRAWINGS

FIGS. 1A and 1B are a view showing an entire system configuration for carrying out the present invention.

FIGS. 2A and 2B show structures of LLaMA according to one embodiment of the present invention, in which FIG. 2A shows an overall structure of LLaMA, and FIG. 2B shows a computational structure within a transformer block.

FIGS. 3A and 3B are diagrams illustrating structures of floating-point and fixed-point according to one embodiment of the present invention.

FIG. 4 is a block diagram of a configuration of a hardware design system for on-device artificial intelligence of large language models according to one embodiment of the present invention.

FIG. 5 is a flowchart for explaining a process of extracting a repeatable and one-to-one node (RON) according to one embodiment of the present invention.

FIGS. 6A to 6D show graphs illustrating a RON configuration according to one embodiment of the present invention.

FIG. 7 is a diagram illustrating a repeating process in an LLM model according to one embodiment of the present invention.

FIG. 8 is a flowchart for explaining a process of finding a bit configuration of fixed-point numbers using fixed-point simulation according to one embodiment of the present invention.

FIGS. 9A and 9B are a flowchart for explaining a process of numerically converting data represented by floating-point numbers into fixed-point numbers according to one embodiment of the present invention.

### DETAILED DESCRIPTION OF THE INVENTION

Hereinafter, embodiments for carrying out the present invention will be described in detail with reference to the accompanying drawings.

In addition, the same reference numeral indicates the same part in the description of the present invention, and repetitive description thereof will be omitted.

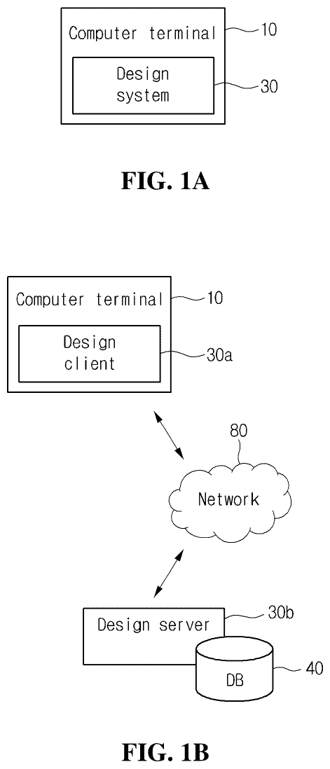

First, examples of the entire system configuration for carrying out the present invention will be described with reference to FIGS. 1A and 1B.

As shown in FIG. 1A, a hardware design system for on-device artificial intelligence of large language models according to the present invention (hereinafter referred to as a design system) may be implemented as a program system on a computer terminal 10, which designs a fixed-point computation structure of a large language model.

In other words, the design system 30 may be implemented as a program system on a computer terminal 10 such as a PC, smartphone, tablet PC, or MP3 terminal. Particularly, the design system may be composed of a program system or a mobile application (or app) so as to be installed and executed on the computer terminal 10. The design system 30 provides a service for designing a fixed-point computation structure of a large language model by using hardware or software resources of the computer terminal 10.

Further, in another embodiment, as shown in FIG. 1B, the design system 30 may be configured and executed as a server-client system composed of a design client 30a and a design server 30b on the computer terminal 10. In other words, the design system 30 may be configured as an online system on a network 80. Herein, a database 40 for storing necessary data may be included.

Meanwhile, the design client 30a and the design server 30b may be implemented according to a typical client and server configuration scheme. In other words, functions of the entire system may be divided depending on the performance of the client or the amount of communication with the server. In other words, it may be implemented in various forms of sharing according to the client-server configuration schemes. In addition, the design server 30b may be configured as a cloud server in which multiple servers are distributed.

In addition, the computer terminal 10 on which the design client 30a is installed may be another online server. In other words, the design server 30b may provide an estimation service to the other online server or site.

Alternatively, in another embodiment, the system according to the present invention may be implemented as one single dedicated IC chip composed of a microprogram and driven by a microprocessor, or implemented as one single electronic circuit such as an application-specific integrated circuit (ASIC). In other words, it may be configured in the form of software or in the form of an electronic circuit formed of an FPGA chip or multiple circuit devices. Other possible forms may also be implemented.

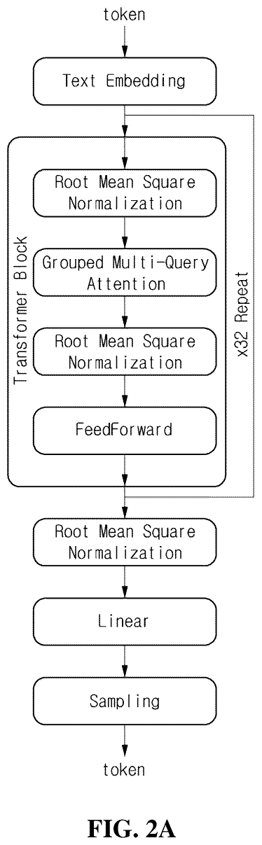

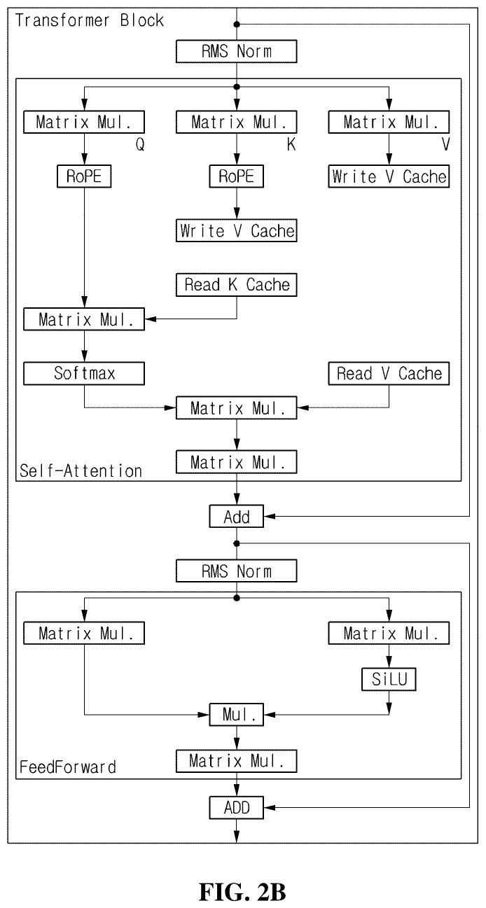

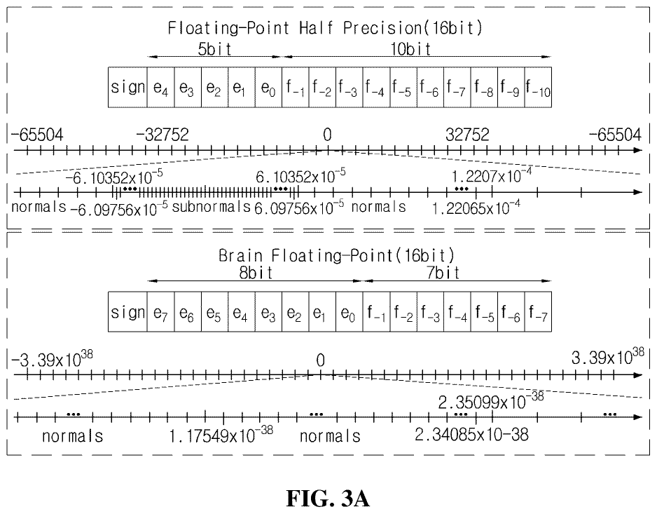

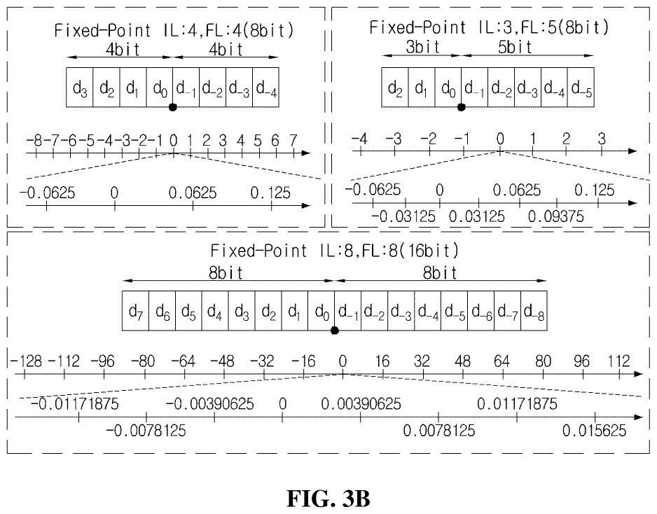

Next, the large language model used in the present invention will be described with reference to FIGS. 2A, 2B, 3A and 3B. Particularly, it will be described on the large language model LLaMA3 as a subject.

Large Language Model Meta AI (LLaMA) refers to the latest language model released by Meta, and exhibits excellent performance in various tasks, such as text generation, translation and summarization, compared to previous open source LLMs. The existing LLAMA series have steadily improved the number of learning parameters and performance with each release, and each series is designed based on the same LLM architecture. LLAMA provides high-performance language models as open source, thereby encouraging the utility in academic and industrial fields and increasing the accessibility of large-scale language models.

The architecture of LLaMA is transformer-based, and each model is optimized to output high performance with few resources. As shown in FIG. 2A, LLaMA has a structure that generates only one token by one forward computation. Multiple forward computations are performed repeatedly to generate an output for the text entered by a user, and during this process, the same parameters are continuously fetched from DRAM. This structure is a common characteristic found not only in LLaMA but also in various LLMs. Particularly, in the case of large scale models, since each forward computation consumes memory and computation resources, efficient memory usage has a significant impact on performance.

The architecture of LLaMA 3 as the target model of the present invention is as shown in FIGS. 2A and 2B. This structure is also used in LLAMA 2, and configured in the form of repeating self-attention and feed-forward computation blocks. Each attention block learns interactions between input tokens, in which, in general, linear transformations into Q, K and V are performed to tensors X introduced as an input, respectively, and then the Softmax computation of the following mathematical equation is performed.

$$softmax ( \frac{{QK}^{T}}{\sqrt{d}} ) V \qquad [ Equation 1 ]$$

Here, d represents a value obtained by dividing the number of dimensions representing each token of LLM in multi-head attention by the number of heads.

Accordingly, the process of understanding the meaning of context is performed, and Rotary Position Embedding (RoPE) is utilized with respect to Q and K, so as to efficiently encode position information between words.

The feed-forward block fine-tunes the meaning of individual tokens through a combination of linear transformations and activation functions. LLaMA uses Sigmoid Linear Unit (SiLU) as a nonlinear activation function in a feed-forward network. SiLU is defined as xσ(x) which is the input x multiplied by sigmoid σ(x), and provides smoother output characteristics compared to ReLU. This makes a gradient flow smoother during the learning process, so as to contribute to preventing excessive gradient vanishing or exploding and improving generalization performance of the model.

In addition, a layer normalization is applied before the self-attention and the feed-forward, and epsilon having used during learning is used in LLaMA at this time. This epsilon value is an initial value used for division in layer normalization, and set to 10⁻⁵ in LLAMA 3. The value is exactly processed in floating-point representation.

As shown in FIG. 2B, the architecture of LLaMA is composed of several transformer blocks, and this block is repeated 32 times in the LLaMA-3-8B model. The number of repetitions is determined during learning, and it is generally known that performance of a model improves as the number of repetitions increases.

However, because all weights in each repeating block have unique values, the number of parameters also increases as the number of blocks increases. As a result, the computational structure of LLaMA and the increase in the number of repetitions increase the number of parameters (i.e., weight capacity) along with the performance improvement, and this creates a trade-off between resource usage efficiency and model performance. The trade-off serves as an important consideration in choosing an optimized model subject to user needs and system resource constraints.

Next, the fixed-point simulation (or integer computation simulation) for the LLM model used in the present invention will be described with reference to FIGS. 3A and 3B.

The fixed-point refers to a bit representation capable of using integer computations, and is faster than floating-point computations and consumes less hardware memory and power. These characteristics make it suitable for fast hardware implementation of neural network models such as CNN and DNN. It is important to set an appropriate bit configuration for each computational node to maximize hardware efficiency, and this is closely related to the design of fixed-point representation.

As shown in FIGS. 3A and 3B, the floating-point may express both of very large and small numbers through exponents, but in the fixed-point, integer bits determine a range of numbers that can be represented, and fractional bits define precision. In addition, the precision interval of the fixed-point is the same throughout the range, but the floating-point formats are not the same. Accordingly, the range and the precision of numbers are required to be simultaneously considered when the fixed-point representation is used, and this becomes an important selection point for the designer.

In other words, as shown in FIGS. 3A and 3B, the floating-point format has non-uniform numeric precision due to an exponential part, and the fixed-point has uniform numeric precision throughout the entire range.

The fixed-point simulation is a process of converting existing floating-point values into fixed-point values to evaluate accuracy and performance in integer computations. The quantization scheme used at this time follows a similar structure to the existing Static Post-Training Quantization (PTQ). Mainly, uniform PTQ is often considered because it is actually identical to integer arithmetic as a result. PTQ uses a uniform quantization formula, such as Equation 2, to convert a floating-point value xfp into an integer value xint having a total of k bits.

$${x}_{i n t} = clamp ( round ( \frac{{x}_{fp}}{s} ) + z , - {2}^{k - 1} , {2}^{k - 1} - 1 ) \qquad [ Equation 2 ]$$

Here, s is a scaling factor and z is a zero-point. The scaling factor adjusts the range and precision of the quantized floating-point value, and the zero point serves to calibrate a distribution center of data.

A value xint quantized by using the following Equation 3 is gone through integer computations, followed by a dequantization process, and restored to the floating-point representation again.

$${x}_{fp} = s ( {x}_{i n t} - z ) \qquad [ Equation 3 ]$$

The fixed-point conversion is similar to the above PTQ scheme, but has some important differences. The fixed-point representation is divided into integer bit length IL and fractional bit length FL, and these two parts represent values using a predefined fixed number of bits. IL ensures that the number range is not exceeded, and FL indicates the precision after the decimal point. The scheme of converting a floating-point value to a fixed-point value may be defined by Equation 4.

$${x}_{fix} = clamp ( round ( {x}_{fp} \times {2}^{FL} ) \times {2}^{- FL} , - {2}^{IL + FL - 1} , {2}^{IL + FL - 1} - 1 ) \qquad [ Equation 4 ]$$

Here, the zero point is not used in fixed-point. This is because the converted value is designed to be directly computed within the integer range. In other words, the fixed-point values can be calculated directly without dequantization. This is because, unlike PTQ, fixed-point computations have determined IL and FL in advance and do not require separate calibrations.

An important factor in the design and implementation of the fixed-point computations is the trade-off between precision and range. When a total bit length is set to k bits, the range of numbers that can be expressed expands but FL decreases as IL increases, thereby resulting in lower precision. In contrast, increasing in FL improves precision but reduces the range of numbers that can be expressed.

The fixed-point simulation is a process of simulating various scenarios to determine the bit configuration and finding the optimal combination. For example, since the distribution of output values of each layer is different in neural networks such as CNN, it is difficult that the fixed bit configuration guarantees optimal performance at all layers. Accordingly, IL and FL suitable for each layer may be determined through simulation, or a scheme such as layer-specific quantization may be applied to minimize precision loss.

As a result, the fixed-point based computations provide significant advantages in terms of memory and power consumption, and are particularly useful in real-time processing and low-power environments. However, in this design process, it is essential to find a bit configuration that can efficiently use computational resources while minimizing precision loss. This requires various simulations and optimization schemes.

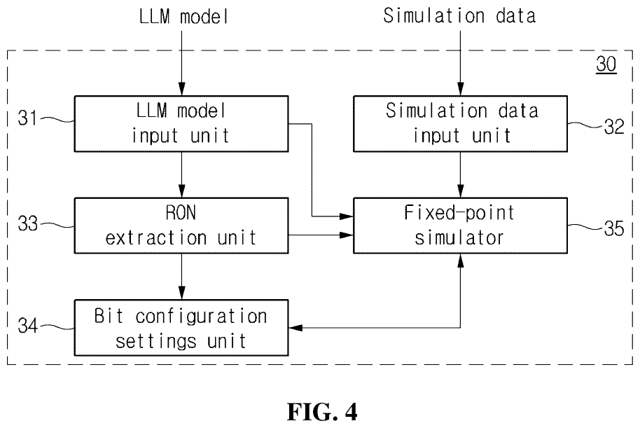

Next, the hardware design system for on-device artificial intelligence of large language models according to one embodiment of the present invention will be described with reference to FIGS. 4 to 9B.

As shown in FIG. 4, the hardware design system 30 for on-device artificial intelligence of large language models according to one embodiment of the present invention includes: a LLM model input unit 31 for receiving an LLM model; a simulation data input unit 32 for receiving simulation data; a RON extraction unit 33 for extracting RON; a fixed-point simulator 35 for simulating fixed points; and a bit configuration setting unit 34 for allowing the fixed points to be simulated and determining a bit configuration based on a simulated result.

When a target LLM for acceleration is determined, an accurate part, to which the fixed-point bit configuration (or integer bit configuration) is applied among multiple computational nodes and repetitive layers of the LLM, is required to be carefully decided to convert the LLM into a model using fast integer computations.

For example, a scheme of maintaining floating-point computations (such as FP16) and implementing only the Softmax part as fixed points to utilize the integer operator may also be considered in SiLU computations. However, there are various combinations, and the floating-point operator may not be available on certain hardware, or a bottleneck may occur during the process of restoring fixed-point values to floating-point values and performing computations. Accordingly, fast integer computations may be implemented without the dequantization process of the existing PTQ by converting all nodes to fixed points.

The various computation blocks of LLM and the precision required for each computation node may be roughly understood by analyzing activation values. However, in order to find the optimal accuracy while maintaining model performance, the integer and fractional bit widths of each computation node are required to be determined based on performance evaluation indicators such as accuracy. Particularly in the task of converting a floating-point model to a fully-integer model, it may be difficult to predict performance changes when computation nodes of floating-point models such as the FP16 model are quantized to fixed-point models such as INT16, INT8 or INT4.

In the case of the LLaMA3 model, which is the LLM model set as the target in the present invention, there is epsilon as a parameter that is a good example showing difficulty in predicting the performance changes. In LLaMA3-8B-Instruct, epsilon is required to be set to 10⁻⁵. This number is smaller than 2⁻¹⁶=0.0000153, and at least 16 bits are required to be assigned as fractional bits in order to express the number in fixed points. It is difficult to know whether these small values are ignored or whether high precision is required, in the preceding and following computations of the computation node using epsilon.

For this reason, the fixed-point simulation is required to be performed while checking the performance indicators. In addition, when the LLM computation nodes are simply divided into several nodes and the bit configuration is set by using only the fixed-point simulation, it is likely to result in inefficient use of limited hardware resources.

Accordingly, according to the present invention, repeatable and one-to-one nodes (RONs) capable of efficiently utilizing hardware resources in target FPGA or ASIC implementation environments are searched while targeting LLM commercial models such as LLAMA3-8B-Instruct, and the fixed-point simulation is performed for each RON.

In other words, in order for the fixed-point computations, the present invention determines the optimal fixed-point bit configuration for all computation nodes computed on floating-point numbers. For example, when the computation result of the fourth RON is a matrix having a size of R1024×4096, and a bit configuration of the fourth RON computation node is IL=5 and FL=9, All data in the 1024×4096 matrix as a result of the fourth RON is configured such that the integer bits are set as 5 bits and fractional bits are set as 9 bits. In this case, when the fifth RON uses the data of the fourth RON, the fixed-point computations (integer computations) may be performed.

First, the LLM model input unit 31 receives an execution model (or execution code) of the LLM model. The execution model of the LLM model refers to a model or code for actually executing the LLM model, and is composed of computation functions and the like, and trained parameter values (such as weights) are trained and set in advance as a trained model.

Specifically, the execution model (or the execution code) of the LLM model is composed of computational functions or computational blocks performed according to a sequence or a flowchart. Preferably, the execution model (or the execution code) of the LLM model may be an execution code written in a high-level programming language, such as Python, used in the field of artificial intelligence. Alternatively, the execution model (or the execution code) of the LLM model may include a flow chart and the like composed of computational functions or computational blocks.

As described above, the LLM model is a typical large language model based on transformers. In other words, preferably, the LLM model is configured in the form of repeating self-attention and feed-forward computation blocks. Particularly, the feedforward block is composed of a combination of linear transformations and activation functions.

Preferably, as shown in FIGS. 2A and 2B, the LLM model is configured in the form of a flowchart or flow diagram that performs each detailed computation. In other words, it may be composed of computation blocks performed in sequence, and a single computation block may be composed of blocks (detailed computation blocks) that perform multiple detailed computations. In other words, the computation blocks may be configured in a hierarchical structure.

Preferably, the computational blocks of the LLM model may be written in the form of a directed graph composed of nodes and edges. In other words, each node performs one computation, and a directed edge connected between the nodes indicates a sequence.

In addition, the computation nodes may be configured and subdivided in a hierarchical structure. For example, a single computation block (node) or an upper block (node) may be composed of multiple detailed computation nodes (blocks) or lower computation blocks (nodes). A transformer computation block (node) may be composed of self-attention computation blocks (nodes) and feedforward computation blocks (nodes). In addition, the feedforward computation block (node) may be further subdivided into matrix computation nodes (blocks), activation function computation nodes (blocks), and the like.

A computation function at each node is composed of functions such as matrix computation (multiplication), activation function, addition and multiplication to perform the corresponding task.

In addition, when an argument required for the computation is a given constant, the constant is also represented by a single node. A computation (storing computation or reading computation) for storing a result value or reading data may also be expressed as nodes. In other words, when the execution model is represented as a directed graph, each node may be a node representing a computation or a constant.

In addition, preferably, the execution model (or the execution code) of the input LLM model is a trained model. In other words, parameters of the execution model are composed of trained and set values.

In addition, preferably, the parameters of the execution model are stored as floating-point numbers.

Next, the simulation data input unit 32 receives simulation data for simulation.

Preferably, the simulation data uses a Massive Multitask Language Understanding (MMLU) dataset. In other words, the simulation execution model of the LLM model is queried using the MMLU data set to obtain an output (answer), and the simulation model (or the simulation execution model) is evaluated based on the results.

In other words, the simulation execution model is set by the bit configuration setting unit 34, the (set) simulation execution model is executed by the fixed-point simulator 35, and the simulation execution model is evaluated based on evaluation of the results. The simulation execution model is executed on the fixed-point simulator 35 with the MMLU data set and the results are output.

Next, the RON extraction unit 33 extracts a RON configuration (or single computation node configuration) from the execution model (or execution code) of the LLM model.

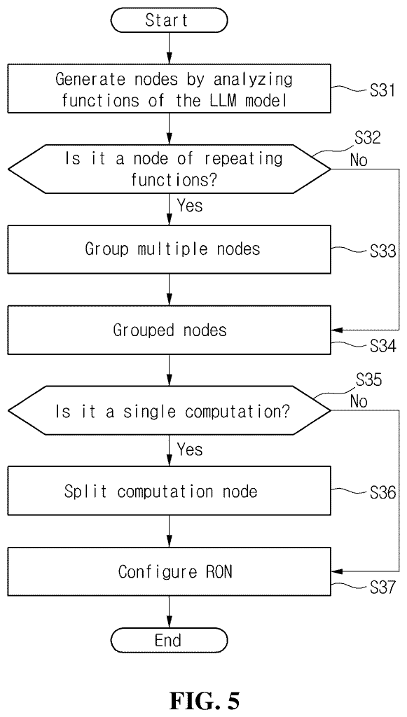

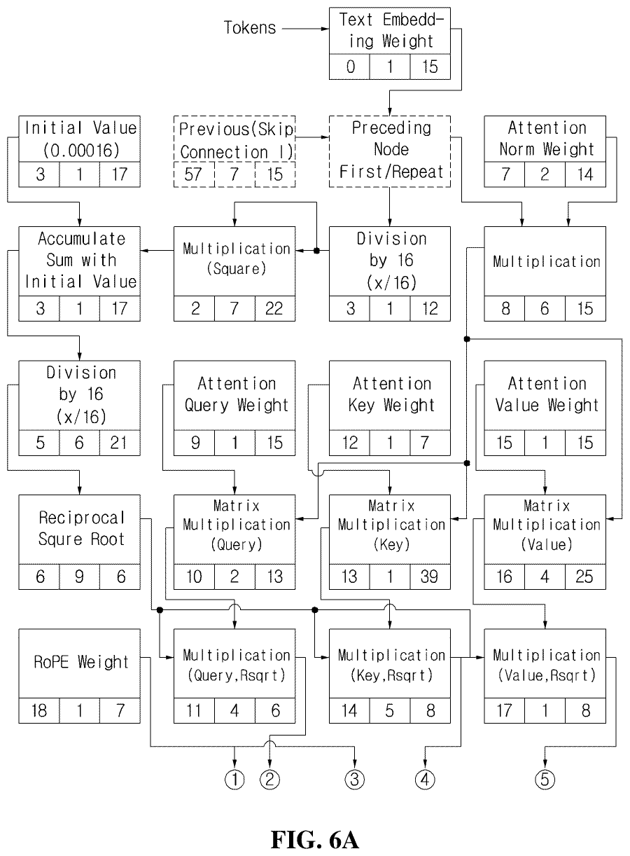

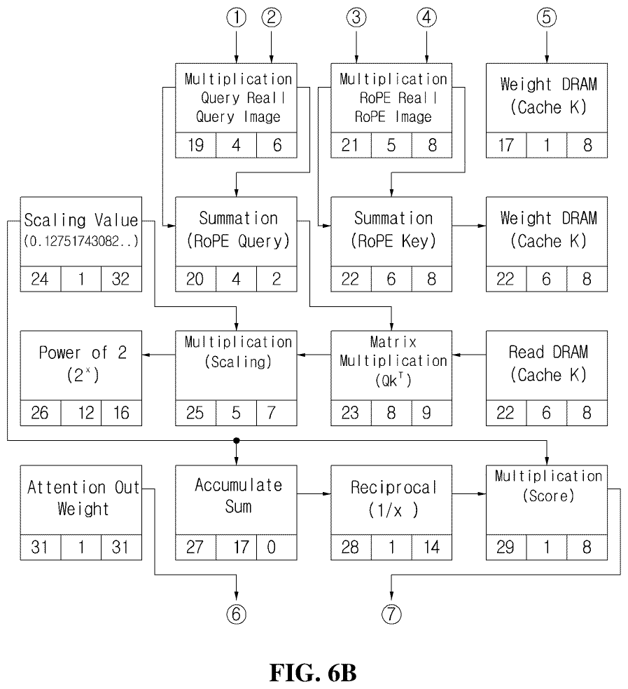

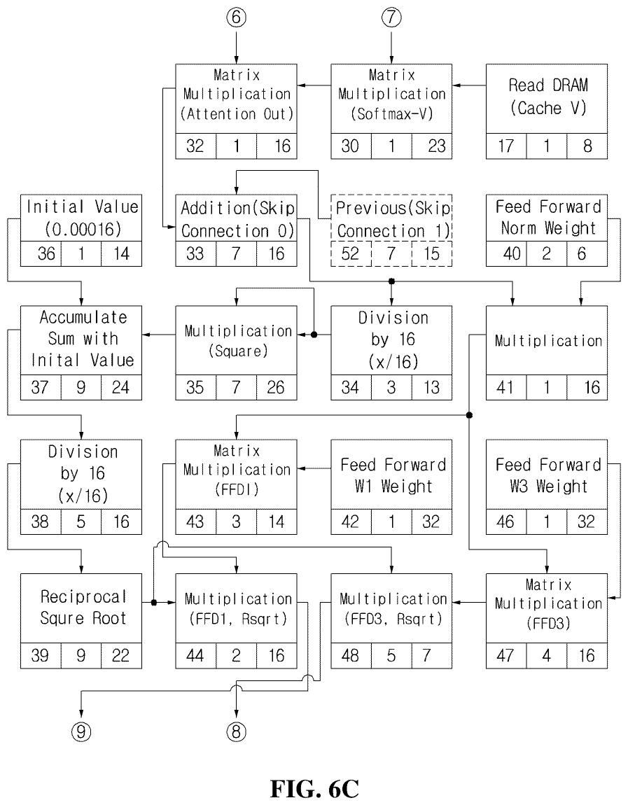

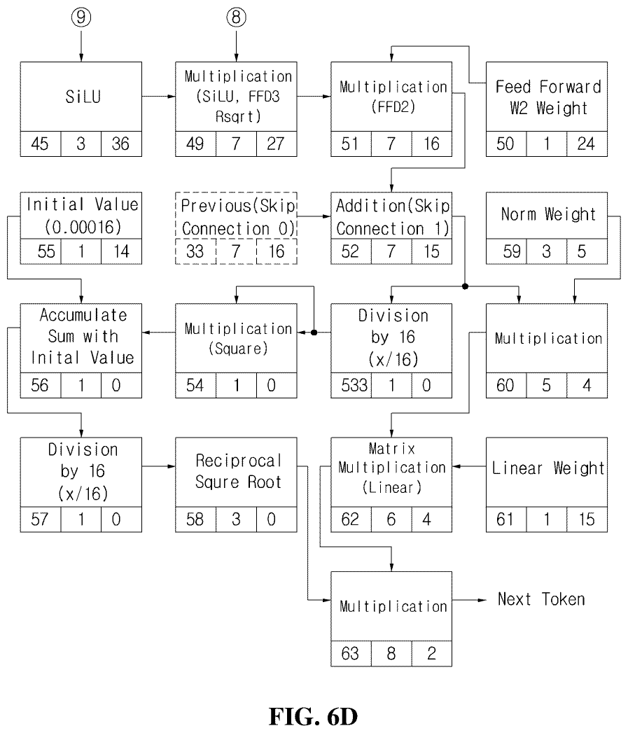

FIG. 5 illustrates the process of obtaining the RON configuration, and FIGS. 6A to 6D illustrate the RON configuration.

As shown in FIG. 5, RON may be obtained through the following process.

First, when a target LLM model is decided, all functions (or computations) of the model (for example, LLaMA3-8B-Instruct or the like) and related constants (constants input to the functions) are analyzed to generate nodes (or computation nodes) corresponding to the functions and constants (or storages) (S31).

In addition to large blocks such as self-attention, feed-forward and layer normalization commonly used in LLM, computations of obtaining Q, K and V for implementing self-attention and computations of dividing √d are also analyzed together.

Particularly, preferably, with respect to the computation blocks (nodes) of the LLM model, the RON extraction unit 33 analyzes computation in each computation block (node) or even in the lowest computation block (node). Preferably, the computation node of each constant or function corresponds to a function or constant at the lowest node.

In addition, the constant refers to a constant inputted to a function (or computation). For example, the matrix computation of the attention query uses a matrix of attention query weights (or a trained constant matrix). As computation nodes, a node of a matrix computation function and a node of a weight constant matrix inputted to the corresponding function computation are generated.

In addition, the computation may also include a storing or reading computation. The storing computation refers to a computation that stores a computed result or output in a specific memory (storage). In addition, the reading computation refers to a computation that reads the stored data.

Meanwhile, when a different constant is inputted even to the same function, the function is determined as a different computation, and accordingly, the constant and the function are generated as a different computation node. For example, matrix multiplication computations for an attention query (Q), an attention key, and an attention value are all the same matrix multiplication computation, but generated as different computation nodes because inputted constants are different. In other words, in the example of FIGS. 6A to 6D, weight computation nodes and matrix multiplication computation nodes are generated separately for each attention query (Q), attention key and attention value.

In addition, RON is not limited to specific functions, but is required to be applied even to constants. This is because fixed-point simulation is required to be performed to find out what IL and FL the epsilon parameters of LLaMA or constants, such as √d, of self-attention are required to have.

Next, after the analysis is completed, it is confirmed whether the function is repeatable (S32). When it is a repeatable function or a repeatable node, the nodes or multiple nodes are grouped (S33). In other words, they are grouped and generated (combined) into one node.

Preferably, the repetition may be determined by whether a repetition occurs in a higher level (node) than a specific node itself. For example, in the case of Python code, it is divided in a unit of class.

In the example of FIGS. 6A to 6D, the attention query weight is included within each transformer block, and the transformer blocks are repeatedly disposed 32 times. Accordingly, the attention query weights are repeatedly computed 32 times. In the above manner, the repeated computation nodes are grouped into multiple nodes. In other words, the function computations corresponding to each transformer block perform computations on different constants, but are determined as similar types and grouped together.

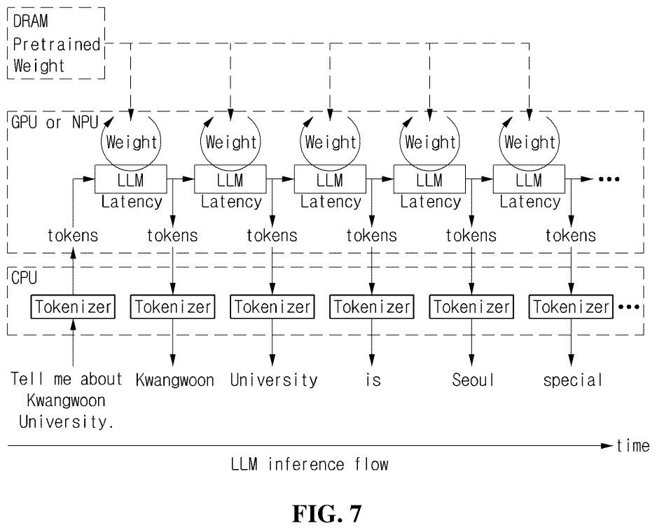

In addition, as shown in FIG. 7, outputs are reused as inputs in the LLM model. The LLM model generates text composed of consecutive words, each word is outputted in a unit. Accordingly, the LLM model repeats each computation within a corresponding block from a start token until reaching an end token.

In addition, when the inputted constants or arguments (outputs of other nodes) are the same and subject to the same type of computations (especially addition computations), or these computations are repeated consecutively, the corresponding computation nodes are also grouped into multiple nodes. For example, a matrix summation of ROPE Query and ROPE Key is a computation composed of addition and subtraction of the preceding matrix multiplication. Since the subtraction is executed as an addition computation in hardware, the addition and the subtraction are the same computation (or the same type of computation). In addition, when the constants inputted and computed are performed consecutively with the same computation, the computations are determined as repetitive computations and grouped.

This process is a process for preventing too many nodes from being generated upon the fixed-point simulation and achieving the same hardware implementations by grouping the same computations.

Next, in the case of node by a function or computation, it is determined whether each function or computation is a single computation (S35), and when the function or computation is not a single computation, it is separated into nodes of multiple single computations (S36).

The single computation is a computation processed by a single operator or calculator. Preferably, the single computation is set in advance, such as addition (matrix sum), multiplication (matrix multiplication), division, inverse matrix, and one-to-one function/computation. In other words, the function or computation of the corresponding computation node is split into a single computation.

For example, when the function of a specific computation node is AB+CD (where A, B, C, D are matrices), the function may be split into two matrix multiplications and one matrix addition.

As another example, the computation such as Softmax is not the one-to-one function, but the function that involved by multiple inputs. When an input vector x is present, Softmax is calculated using Equation 5.

$$softmax ( x ) = \frac{{e}^{z}}{{\sum }_{j} {e}^{{z}_{i}}} \qquad [ Equation 5 ]$$

This is a splitable computation, and each may be split into one-to-one functions such as e^{x}

$${\sum }_{j} {e}^{xj}$$

and 1/x. Thus, Softmax may be split into three RONs. For the reference, since

$${\sum }_{j} {e}^{xj}$$

is a form of a cumulative sum of multiple e^{x} (single functions), it is classified as a single computation corresponding to addition.

Meanwhile, a splitable one-to-one function may be present. The SiLU function may be used as an example, and expressed as Equation 6 for the input vector x.

$$SiLU ( x ) = \frac{x}{1 + {e}^{- x}} \qquad [ Equation 6 ]$$

The equation may be split into multiplication, 1+x, e^{-x} and 1/x, but correspond to the one-to-one function. Accordingly, the SiLU function may not be split into a single computation node.

Particularly, the one-to-one function may be implemented by replacement with a lookup table (LUT) without complex computations, or by applying an approximation function. Accordingly, only IL and FL for an input and an output of the function are searched in the fixed-point simulation.

Meanwhile, when a node for computation is split into multiple single nodes (single computation nodes), constant nodes coming as inputs by the corresponding computation nodes are also split or connected to a split single node. In other words, the constant is connected to a single node used as an input among the split single nodes.

Next, RON is configured by using the obtained single computation nodes (S37).

An example of the configuration of a final configured RON node (a repeatable single computation node or single node) is shown in FIGS. 6A to 6D. In FIGS. 6A to 6D, the quadrangle boxes represent RON nodes. FIGS. 6A to 6D also indicate a bit configuration of each RON node (to be set later). In each quadrangle box, the first box among the three boxes at the bottom is the number of the RON node, the second box is IL (integer bits), and the third box is FL (fractional bits).

As shown in FIGS. 6A-6D, each single node in the RON configuration represents a constant or a computation. In the example of FIGS. 6A-6D, the attention query weight node or the like represents a constants or constant matrix, and a matrix multiplication node, summation or the like represents a computation.

The bit configuration of each single node is fully reflected in the bit configuration of the number (data) stored during or after the computation. In other words, when a bit configuration of a specific single node is set, constants of the single node or input and output values of the computation are all set identical to the bit configuration.

In addition, since each single node is a grouped node as a repeatable node, bit configurations of all nodes grouped into the corresponding single node are also set identically. In the example of FIGS. 6A-6D, when a bit configuration of a single node of the attention query weight is set, all nodes in corresponding groups of all transformers (all transformers repeated 32 times in Llama3) are also set to the identical bit configuration.

Next, the fixed-point simulator 35 performs fixed-point simulation.

In other words, the fixed-point simulator 35 executes the execution model (or execution code) of the LLM model, so as to process computations of arguments by fixed-point numbers when each function or computation is performed.

Specifically, the fixed-point simulator 35 receives an execution model (or execution code) of the LLM model, simulation input data, and a bit configuration of a fixed-point of each constant or computation (function) (or computation node).

As described above, the execution model (or execution code) of the LLM model is composed of an execution model or execution code of commercialized LLM models such as Llama3. The fixed-point simulator 35 executes the execution code of the LLM model without modification.

In addition, the fixed-point simulator 35 inputs the given simulation input data into the LLM model to simulate the LLM model and output results. As described above, the simulation input data is composed of an MMLU data set.

In addition, when the execution code of the LLM model is simulated to performing each computation within the execution code, the fixed-point simulator 35 configures bits of each constant or argument according to the inputted bit configuration. For example, when the bit configuration of the attention query weight is set to <IL, FL>=<5,10> or the like, all matrices of attention query weights are converted by fixed-point numbers of the bit configuration. In other words, the attention query weights given by the execution model of the LLM model are configured and inputted as floating-point numbers. The attention query weights of the corresponding floating-point numbers are converted by fixed-point numbers of the corresponding bit configuration.

In addition, when a specific computation in the execution code of the LLM model is simulated, the fixed-point simulator 35 converts the fixed-point number of the argument inputted according to the bit configuration of the corresponding input argument. For example, when the initial bit configuration of the input argument is <7,8> and the bit configuration of the corresponding computation is <5,10>, the input argument is converted from <7,8> to <5,10>. In this case, the top two bits of the input argument are lost.

In addition, when the bit configuration of each constant or computation (or computation node) is not set, the fixed-point simulator 35 simulates with floating-point numbers. In other words, the fixed-point simulator 35 may simulate only a part of the bit configuration of the given fixed-point numbers according to an instruction (input) of the bit configuration, and simulate the rest as the initial floating-point numbers. In other words, the fixed-point simulator sets, according to the input, whether the bit configuration of each constant or computation is to be computed as a fixed-point bit configuration or a floating-point configuration.

Meanwhile, in order to automatically perform simulation of the execution model of the LLM model, the fixed-point simulator 35 is designed to perform large-scale parallel computations using graphics processors (GPGPU) or processors for artificial intelligence.

Next, the bit configuration setting unit 34 sets multiple bit configurations, controls the fixed-point simulator 35 to simulate the set bit configuration, and evaluates the simulation results to determine the final bit configuration.

In other words, the bit configuration setting unit 34 sets the bit configuration of each constant or computation (or computation argument) of the execution model of the LLM model according to the bit configuration of each single node of the RON configuration, simulates the fixed-point simulator 35 according to the set bit configuration to obtain the results, and evaluates the obtained results to find out the optimal bit configuration.

For example, when the fixed-point bit configuration of the seventh attention norm weight of the RON configuration in FIGS. 6A-6D is set to <IL,FL>=<4,8>, the fixed-point simulator 35 simulates the bit configuration of all grouped attention norm weights of the execution model of the LLM model by setting as <IL,FL>=<4,8>. In other words, the bit configuration of the attention norm weights is set to <IL,FL>=<4,8> and simulated in all 32 Transformer blocks in the simulation.

In addition, the results evaluation is performed by simulating the MMLU data set and evaluating whether the results match correct answers for the MMLU data. Preferably, evaluation criteria are set by the correct answer rate of the MMLU data set. For example, there may be a multiple choice question in the MMLU dataset, in which 1 point may be scored for a correct answer right and 0 point may be scored for a wrong answer. When about 150 questions are extracted from the MMLU dataset of about 3,000 questions and inputted into LLaMA (LLM), answers may be obtained, and accordingly accuracy may be determined. In other words, the bit configuration setting unit 34 determines whether each MMLU data is correct with respect to the bit configuration of the RON node of the RON configuration, and calculates the correct answer rate for the tested MMLU data, and selects the optimal bit configuration for the bit configuration of the corresponding RON node when the correct answer rate is equal to or higher than a pre-determined threshold.

Meanwhile, the bit configuration setting unit 34 firstly performs an integer-only fixed-point simulation step of setting up the integer bit (IL) configuration, and performs a fraction-only fixed-point simulation step of setting up the fractional bit (FL) configuration afterward. The integer bits (IL) and the fractional bits (FL) finally set at each step are set to the final overall bit configuration.

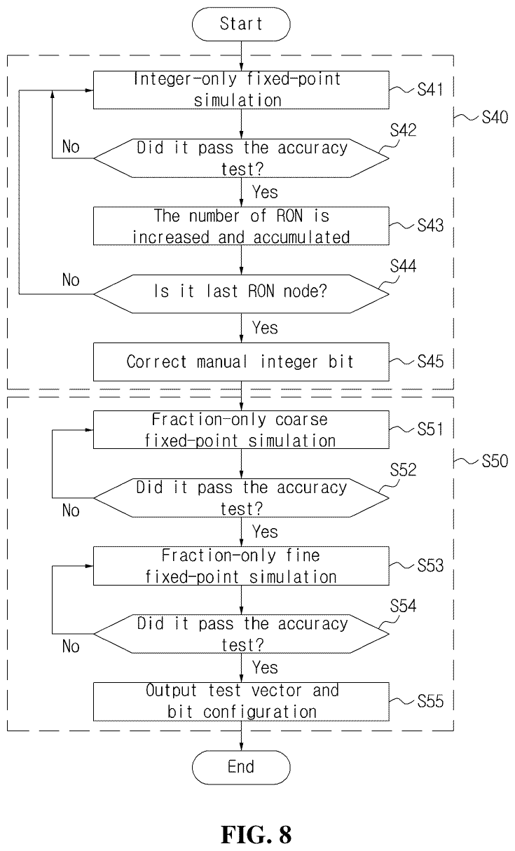

FIG. 8 shows a method for finding out the bit configuration by the fixed-point simulation. As shown in FIG. 8, the method includes performing an integer-only fixed-point simulation step S40 for deciding IL, and a fraction-only fixed-point simulation step S50 for deciding FL.

The integer-only fixed-point simulation step is the step of deciding an extent to which each RON node is required to express the data. Since the fixed-point simulation is performed in a bit unit while measuring accuracy, the simulation is performed while accumulating results for all RON nodes.

In other words, each node is simulated sequentially according to the RON structure (S41), and an accuracy test is performed on each node, thereby determining whether the node passes or fails (S42). When one node is completed within the RON, the number of RON is increased and accumulated (S43). These processes are performed until the last node of the RON structure (S44).

The accumulation herein signifies that the next RON node is simulated while maintaining the results of the previous RON node. For example, the fourth RON node is converted with fixed points, so as to be changed to a quantized fixed-point representation of 7.75 with respect to initial data of 7.9. When the simulation is complete and the fixed-point bit configuration is confirmed, it signifies that the LLM model is required to be continuously computed using the data of 7.75 upon simulation of the next RON node.

Meanwhile, in the integer-only simulation, integer bits are simulated by setting various bit configurations, while the fractional bits are set to the largest bit as possible. Preferably, the remaining bit size after subtracting the integer bits from the maximum bits of the fixed-point number is set as fractional bits. For example, when the maximum bits of the fixed-point number (integer/decimal) are 52 and the integer bits are set to IL, the simulation proceeds while fixing the maximum value of the fractional bit FL at FL=52−IL.

In the case of integer-only task, a decrease in data range due to IL reduction may propagate to a rear-side RON, thereby resulting in parts in which IL becomes unnecessarily larger than the actual computed value. Since the LLM model has a repetitive structure, there may be cases in which bit width of a front-side node (RON) is further reduced by the rear-side node (RON). This is a problem occurring for RONs that lead to skip-connections inside LLM, and this requires a process of manually modifying the values from the front-side and rear-side RONs (S45). In other words, it may be modified based on user input.

As described above, the bit configuration setting unit 34 sequentially applies to the fixed-point simulation to each single node in the RON configuration. In other words, the fixed-point simulation is performed in order to set the bit configuration of a single node that starts first in the RON configuration. When the bit configuration of the single node is completed, simulation for a bit configuration of a next single node is performed.

Specifically, in order to set a bit configuration of a single node starting from a directed graph of the RON configuration, a bit configuration of the single node is configured to a specific fixed point, and bit configurations of the latter remaining single nodes are configured as the initial floating points as they are, thereby performing the simulation. After completing the bit configuration of the single node starting as above, the simulations for the bit configuration of the next single node is performed. At this time, all single nodes in the previous order of the corresponding single node set the bit configuration of the completed fixed point, and the subsequent single nodes of the corresponding node are configuring as the initial floating point and simulated.

In other words, the bit configuration setting unit 34 sequentially performs the (integer-only) fixed-point simulation for each single node according to the node sequence (by edge orientation) of the RON configuration, in which the bit configuration of the nodes in the previous order of the single node is set as the bit configuration of the fixed point previously set (by simulation), and the bit configuration of the nodes in the next order of the single node is configured as the initial floating point.

This is because, when the simulation of the front-side RON node (the single node in the RON configuration) in the LLM data generation step is not completed, but the RON node for the rear-side is simulated, the range or precision of the fixed-point may incorrectly propagate to the subsequent computations.

For example, it is assumed that number 5.251 is present and a corresponding node is set to an integer part IL=3. In this case, since 1 bit of the integer part IL=3 is a bit representing a sign, the remaining 2 bits are required to be used to represent the integer. Accordingly, since the maximum expressible value is 112=310, the integer part of number 5.251 is limited from 5 to 3. The simulation is performed while increasing IL by 1 from IL=1 to IL=21. In the case that performance of the LLM model is maintained even though the simulation result of number 5.251 is changed to 3.251 when IL=3, it is advantageous because fewer bits are usable. The fractional part is in the same manner.

However, this process takes too long. In addition, since small number of bits may significantly distort the initial data, it is split into two steps. In a coarse step, the simulation is performed by sparsely skipping through 8-bit units. When it is simulated with IL=1, 8, 16, 24, . . . , and the performance reaches a targeted value at IL=24, afterward, it moves to a fine step to find the smallest bit, such as IL=23, 22, 21, 20, 19, . . . , corresponding to the targeted value by 1 bit unit.

In other words, preferably, the fraction-only step S50 described later proceeds in two steps: the coarse step and the fine step. In the integer-only step S40, the simulation may be performed in two steps: the coarse step and the fine step. However, in the integer-only step S40, only the fine step may be performed when the maximum size of the integer bits is small.

Next, after the integer-only fixed-point simulation, the fixed-point simulation for determining FL is performed (S50).

The fraction-only simulation step S50 is similar to the previous integer-only simulation step S40. In other words, the bit configuration setting unit 34 sequentially applies the fraction-only fixed-point simulation to each single node in the RON configuration. In other words, the fraction-only fixed-point simulation is performed in order to set the bit configuration of the single node starting first in the RON configuration. When the bit configuration of the single node is completed, the fraction-only simulation for a bit configuration of a next single node is performed.

In all bit configurations of the RON configuration, the integer bit configuration is the same as the integer bit configuration that is previously obtained in the integer-only step S40. The fractional bit configuration of the node following the currently proceeding RON node is set to the maximum bit size as possible, and preferably, the remaining bit size after subtracting the integer bits from the maximum bits of the fixed-point number is set as fractional bits.

Specifically, in other words, the bit configuration setting unit 34 sequentially performs the fraction-only fixed-point simulation for each single node according to the node sequence (by edge orientation) of the RON configuration, in which the bit configuration of the nodes in the previous order of the single node is set as the integer and fractional bit configuration of the fixed point previously set (by simulation), and the bit configuration of the nodes in the subsequent order of the node is set as the integer bit configuration obtained from the previous integer-only simulation and the fractional bit configuration of the possible maximum bits.

Meanwhile, in the fraction-only simulation step S50, a specific bit is required to be determined as an optimal bit between the minimum bit (e.g. 0) and the possible maximum bit (e.g. 52 bits). The possible maximum bits refers to the number of bits remaining after subtracting the number of integer bits from the maximum number of bits (maximum number of bits) of the fixed-point number. For example, when the number of integer bits is set to 5 bits in advance, the possible fractional bits are 52−5=47 bits. Accordingly, in the fraction-only, the fractional bit is required to select (extract) any one of 0 to 47 bits.

It includes coarse fixed-point simulation processes S51 to S52 performed in units of 2 or more bits, and fine fixed-point simulation processes S53 to S54 performed in 1-bit units.

In other words, the approximate fractional bit configuration is found by the coarse steps S51 to S52, and then the fractional bit configuration is precisely found in 1-bit units by the fine steps S53 to S54. For example, when the coarse bit unit is 8 bits, the simulation is performed sparsely in 8-bit units. Then, when a bit satisfying reference accuracy is present, the simulation is performed again in the direction of lower bits. It is performed unit the smaller number of bits before the optimal coarse bit by one less bit unit. In other words, when the integer bit size is sequentially performed in multiples of 8, such as 8, 16, 24, 32, . . . , and when 16 bits is optimal thereamong, the optimal bit configuration is found by sequentially performing 15, 14, 13, 12, 11, 10, and 9 bits. In other words, since the bit unit less than the coarse bit unit of 16 bits is 8 bits, the fine step is performed up to 9 bits which is before 8 bits.

Meanwhile, the optimal bit is the fewer bit while maintaining the accuracy most.

Next, when IL and FL are determined for all RON nodes, a fixed-point test vector and a corresponding bit configuration for hardware design are stored through a single forward computation, and accordingly, the fixed-point conversion of LLM is finished (S55).

Here, when input (one or multiple tokens) is given to the entire deep learning model, that is, the LLM model, one token is generated. The procedure up to this process is called forward.

In addition, the test vector represents data that has been changed by the RON node, regardless of what the original data was. Any simulation data may be used for the test vector. When RON is fixed, the same values may always appear in each RON node for the same simulation data. This may be used for verification purposes at the hardware design stage and used as a test vector when viewed in the above meaning.

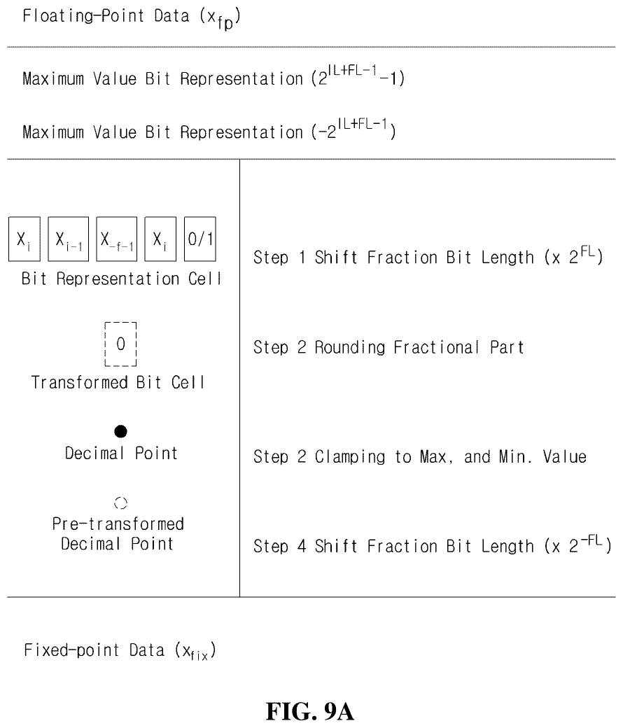

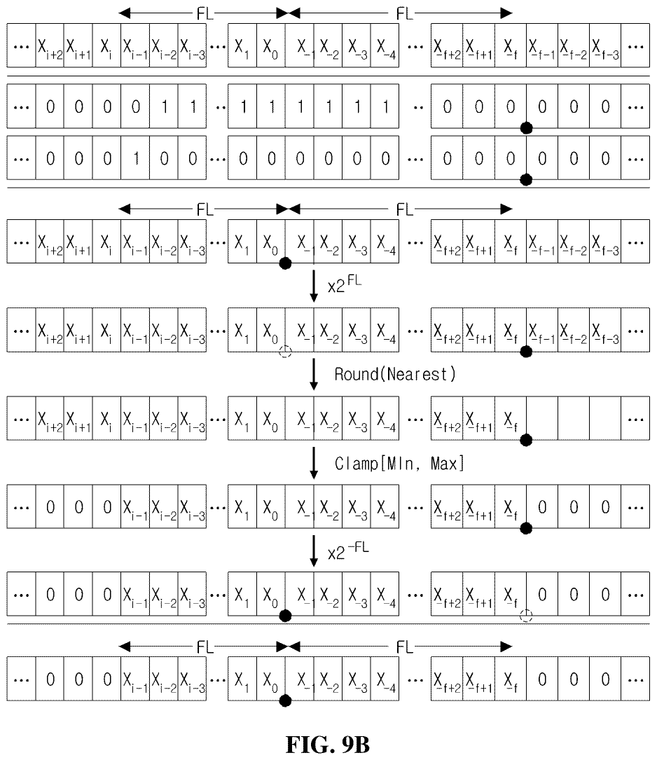

Next, a fixed-point conversion method applied to RON according to one embodiment of the present invention will be described with reference to FIGS. 9A and 9B. The above method is performed by the fixed-point simulator 35.

FIGS. 9A and 9B show a process of numerically converting data represented by floating-point numbers into fixed-point numbers. The values expressed as xfp are converted to xfix in a total of four steps by applying shifts and rounds to match the target IL and FL.

The data of the RON node represented in floating-point may be applied to the target IL and FL of each fixed-point simulation through a total of four steps. These calculations are performed using a double precision type defined in IEEE 754 to accommodate as many ILs and FLs as possible. The fractional part of the double precision type is 52 bits in total, in which the fixed-point conversion may be performed without overflow upon IL+FL≤52.

Each conversion step is as follows. In step 1 of FIGS. 9A and 9B, xfp is multiplied by 2FL to move the decimal point of data represented as floating-point number to the right by FL. Thereafter, in step 2, it rounds to the nearest integer. At this time, all bits less than FL from the decimal point round off and disappear. In step 3 the maximum and minimum values of the fixed-point represented by IL and FL are calculated and clamped. In step 4, the result value of step 3 is multiplied by 2-FL to move the decimal point to the left by IL, thereby finally calculating the fixed-point data xfix.

Meanwhile, since only IL is determined in the integer-only simulation, the simulation is performed while the maximum value of FL is fixed at FL=52-IL so as to determine the IL for all RONs. When IL is determined, the simulation for searching the appropriate FL by using the IL determined for each RON is performed. The range of FL becomes 0≤FL≤52-IL.

This process may be processed in parallel using CUDA through floating-point variables (double precision type) expressed in the double precision type. The unit computed in parallel is RON. Because repeatable nodes are grouped at the time when RON is determined, it may be easily implemented by simply describing IL and FL to be simulated for each RON. In addition, since all data is stored within the fractional part of 52 bits of double precision type to perform calculations, a bitstream corresponding to a test vector suitable for each RON may be obtained in advance. Accordingly, the LLM model may be converted to fixed-point, and test vectors for accurate verification during hardware design may be obtained.

The present invention proposes a fixed-point simulation-based full integer computation method for the LLaMA3-8B-Instruct model. Floating point computation dependency is eliminated in on-device execution of large language models (LLMs), and efficient integer computations is implemented without accuracy loss, so that the use of hardware resources is optimized.

According to the present invention, the computational blocks of the LLaMA3-8B-Instruct model are split into the Repeatable and One-to-One Nodes (RONs), and the fixed-point simulation for optimizing the integer and fractional bits for each RON is performed. Accordingly, integer arithmetic of the model can be achieved while maintaining the same MMLU accuracy (67.25%) as FP16 that is a baseline.

Based on hardware resource analysis results using a synopsis design compiler, the fixed-point simulation can save up to 64.07% of hardware resources, and this proves that it enables more efficient hardware design compared to floating-point computations. In addition, the test vectors generated during the fixed-point simulation can be usefully utilized in the hardware design and verification stages.

The present invention proposes a new method capable of implementing the fully-integer computations on the entire LLM to overcome the limitations of the existing PTQ scheme, so that high performance and efficiency can be maintained even in environments without floating point operators.

The present invention implemented by the inventor has been described in detail according to the above embodiments, however, the present invention is not limited to the embodiments and various modifications are available within the scope without departing from the invention.

What is claimed is:

1. A hardware design system for on-device artificial intelligence of large language models, the hardware design system comprising:
a LLM model input unit for receiving a trained LLM model;
a simulation data input unit for receiving simulation data;
a RON extraction unit for extracting a RON configuration from a configuration of the LLM model, in which the RON configuration is composed of a repeatable single node (RON node) representing constants or computations;
a fixed-point simulator for simulating an execution of the LLM model by using the simulation data, in which some or all of constants or computations of the LLM model are simulated by fixed-point bit configurations, and the bit configuration of each constant or computation is given; and
a bit configuration setting unit for setting a bit configuration of each RON node in the RON configuration, in which the bit configuration of a corresponding RON node is set to perform simulation through the fixed-point simulator, and a final bit configuration of the corresponding RON node is set based on a result of the simulation.

2. The hardware design system of claim 1, wherein the RON extraction unit generates the RON configuration by performing a method comprising:
(a1) a step of extracting a computation node corresponding to each constant or computation of the LLM model;
(a2) a step of determining whether the extracted computation node is a repeatable node, and grouping repeatable nodes so as to be generated as one node;
(a3) a step of determining whether each node is a single node, and splitting non-single node into single nodes; and
(a4) a step of determining a final RON configuration by using all of the single nodes.

3. The hardware design system of claim 2, wherein, in the step (a2), when each computation node of the LLM model has a repetition in an upper node thereof or when inputted constants or arguments are identical and identical type of consecutive computations are repeated, the RON extraction unit determines the computation node as a repeatable node.

4. The hardware design system of claim 2, wherein, in the step (a3), the RON extraction unit determines the computation node, which is a one-to-one function or a node having a replaced lookup table (LUT) or approximation function, as a single computation.

5. The hardware design system of claim 1, wherein the bit configuration setting unit is subject to a bit configuration of a specific RON node of the RON configuration to set bit configurations of all of the constants or computations of the LLM model belonging to the RON node, simulates the fixed-point simulator to obtain a result, and evaluates the obtained result to find an optimal bit configuration for the RON node.

6. The hardware design system of claim 1, wherein the simulation data includes a massive multitask language understanding (MMLU) data set, and the bit configuration setting unit determines whether each of the simulation data is correct with respect to the bit configuration of the RON node of the RON configuration, and calculates a correct answer rate for the entire simulation data, thereby selecting a bit configuration of the RON node as an optimal bit configuration when the correct answer rate is equal to or higher than a predetermined threshold.

7. The hardware design system of claim 1, wherein the bit configuration setting unit performs an integer-only step of setting an integer bit configuration from the fixed-point bit configurations, and then performs a fraction-only step of setting a fractional bit configuration when the integer bit configuration is set.

8. The hardware design system of claim 7, wherein the bit configuration setting unit performs fixed-point simulation sequentially for each RON node according to a sequence of RON nodes in the RON configuration to set an optimal bit configuration, in which bit configurations of RON nodes preceding a corresponding RON node are set as a bit configuration of an extracted optimal fixed-point, and bit configurations of RON nodes following the corresponding RON node are set as an initial floating point or possible maximum bits.

9. The hardware design system of claim 8, wherein, in the integer-only step and when an optimal integer bit configuration of each RON node is sequentially extracted according to a RON node sequence of the RON configuration, the bit configuration setting unit sets the bit configurations of the RON nodes preceding the corresponding RON node as extracted optimal integer bits and fractional bits having a remaining bit size after subtracting the integer bits from a maximum bits of the fixed point, and sets the bit configurations of the RON nodes following the corresponding RON node as floating point; and wherein,
in the fraction-only step and when an optimal fractional bit configuration of each RON node is sequentially extracted according to the RON node sequence of the RON configuration, the bit configuration setting unit sets the bit configurations of the RON nodes preceding the corresponding RON node as extracted optimal integer bits and extracted optimal fractional bits, and sets the bit configurations of the RON nodes following the corresponding RON node as extracted optimal integer bits and fractional bits having a remaining bit size after subtracting the integer bits from a maximum bits of the fixed point.

10. The hardware design system of claim 1, wherein the bit configuration setting unit sets any one bit between a predetermined minimum bit and a possible maximum bit as an optimal bit, and performs a coarse step of finding the optimal bit in predetermined 2-bit units or more, and a fine step of finding the optimal bit in a 1-bit unit from the coarse step.

11. The hardware design system of claim 1, wherein the fixed-point simulator converts data value xfp of the RON node represented in floating point to fixed point, by converting the data value xfp to the fixed point by performing a method comprising:
a first step, when integer bits are set as IL and the fractional bits are set as FL, of multiplying the data value xfp by 2FL to move a decimal point of data represented as a floating point rightward by FL;
a second step of rounding off the value obtained in the first step to a nearest integer;
a third step of calculating and clamping maximum and minimum values of a fixed-point represented by IL and FL; and
a step of calculating fixed-point data xfix by moving the decimal point leftward by IL.
